(19) United States
(12) Patent Application Publication
(10) Pub. No.: US 2007/0194350 A1
(43) Pub. Date: Aug. 23, 2007

(54) SEMICONDUCTOR DEVICE

(75) Inventors: Yasuo HIROOKA, Kadoma-shi, Osaka (JP); Shingo HASHIZUME, Kadoma-shi, Osaka (JP); Michiya OHTSUJI, Kadoma-shi, Osaka (JP); Tomonari OOTA, Kadoma-shi, Osaka (JP)

Correspondence Address: HAMRE, SCHUMANN, MUELLER & LARSON, P.C., P.O.BOX 2902, MINNEAPOLIS, MN, 55402-0902, US

(73) Assignee: MATSUSHITA ELECTRIC INDUSTRIAL CO., LTD., Osaka (JP)

(21) Appl. No.: 11/531,860

(22) Filed: Sep. 14, 2006

(30) Foreign Application Priority Data
Sep. 15, 2005 (JP) 2005-268827

(51) Int. Cl. H01L 29/768

(52) U.S. Cl. 257/220

(57) ABSTRACT

A semiconductor device includes the following: a well layer formed in the surface region of a silicon layer; a source layer formed in the surface region of the well layer; a high-concentration well layer formed in the well layer so that its depth from the surface of the silicon layer is shallower than the well layer and deeper than the source layer; a gate electrode formed linearly across the silicon layer, the well layer, and the source layer; a first contact region connected electrically to the source layer; second contact regions arranged at predetermined intervals in the direction parallel to the gate electrode within the first contact region and connected electrically to the high-concentration well layer; and a source electrode connected electrically to the first and second contact regions. The source electrode is connected to either the first contact region or the second contact region in any cross section perpendicular to the longitudinal direction of the gate electrode. This semiconductor device can improve the avalanche resistance.

### BACKGROUND OF THE INVENTION

1. Field of the Invention

The present invention relates to a semiconductor device such as a vertical MOS (metal-oxide-semiconductor) field-effect transistor.

2. Description of Related Art

A conventional vertical MOS field-effect transistor is configured, e.g., as shown in FIGS. 9 to 11. FIG. 9 is a plan view showing the state after forming a source region in the surface of the conventional vertical MOS field-effect transistor. FIG. 10 is a cross-sectional view taken along the line E-E′ in FIG. 9. FIG. 11 is a cross-sectional view taken along the line E-E′ in FIG. 9 after forming a source electrode.

In FIG. 9, reference numeral 61 is a gate electrode made of polysilicon, 62 is a source contact surface, and 63 is a P-type high-concentration body contact surface.

In FIG. 10, reference numeral 66 is an N-type silicon substrate, and a P-type well layer 64 is formed in the surface region of the N-type silicon substrate 66. In the P-type well layer 64, a P-type high-concentration well layer 73 is formed along with an N-type source layer 72. A gate oxide film 65 is formed on the N-type silicon substrate 66 other than the portion corresponding to the P-type high-concentration well layer 73 and part of the N-type source layer 72. A gate electrode 61 is formed on the gate oxide film 65.

When this vertical MOS field-effect transistor is produced as shown in FIG. 10, first, an oxide film and a polysilicon layer are formed successively on the N-type silicon substrate 66, and then patterning is performed to form the gate oxide film 65 and the gate electrode 61. Next, using the gate electrode 61 as a mask, P-type impurities are ion-implanted into the N-type silicon substrate 66, thereby forming the P-type well layer 64. Next, using the photoresist formed by patterning as a mask, high-concentration P-type impurities are ion-implanted into the P-type well layer 64, thereby forming the P-type high-concentration well layer 73. Next, using the photoresist formed by patterning as a mask, N-type impurities are ion-implanted into the P-type well layer 64 and the P-type high-concentration well layer 73, thereby forming the N-type source layer 72. The P-type high-concentration well layer 73 serves to provide good avalanche resistance by improving the contact property of the vertical MOS field-effect transistor and reducing the resistance component of the P-type well layer 64.

Subsequently, as shown in FIG. 11, a protective film 67 is formed on the gate electrode 61 and the N-type silicon substrate 66. Then, a contact hole 69 is formed on the P-type high-concentration well layer 73 and part of the N-type source layer 72. Finally, a source electrode 68 is formed on the protective film 67. A drain electrode (not shown) is formed on the underside of the N-type silicon substrate 66.

As shown in FIG. 11, the source electrode 68 comes into contact with the N-type source layer 72 while sandwiching the P-type high-concentration well layer 73 via the contact hole 69 in the same cross section. Therefore, as a distance between the adjacent gate electrodes 61 is finer, it becomes more difficult to bring the source electrode 68 into contact with both the P-type well layer 64 and the P-type high-concentration well layer 73 via the contact hole 69. Moreover, if the mask is displaced during the formation of the N-type source layer 72, the source electrode 68 cannot come into contact with the P-type high-concentration well layer 73 via the contact hole 69.

As shown in FIG. 11, the source electrode 68 comes into contact with not only the P-type high-concentration well layer 73, but also part of the N-type source layer 72 via the contact hole 69. Thus, the contact area between the source electrode 68 and the P-type high-concentration well layer 73 is reduced, increasing the resistance components of the P-type well layer 64 under the N-type source layer 72 and the P-type high-concentration well layer 73. Consequently, a parasitic bipolar transistor of the vertical MOS field-effect transistor is turned on easily, and the avalanche resistance becomes poor.

Another conventional vertical MOS field-effect transistor is known and disclosed, e.g., by Japanese Patent No. 3204792. The vertical MOS field-effect transistor is configured as shown in FIGS. 12 to 16. FIG. 12 is a plan view showing the state after forming a source region in the surface of the conventional vertical MOS field-effect transistor. FIG. 13 is a cross-sectional view taken along the line C-C′ in FIG. 12. FIG. 14 is a cross-sectional view taken along the line D-D′ in FIG. 12. FIG. 15 is a cross-sectional view taken along the line C-C′ in FIG. 12 after forming a source electrode. FIG. 16 is a cross-sectional view taken along the line D-D′ in FIG. 12 after forming a source electrode.

In FIG. 12, reference numeral 91 is a gate electrode made of polysilicon, 92 is a source contact surface, and 93 are P-type high-concentration body contact surfaces.

In FIGS. 13 and 14, reference numeral 96 is an N-type silicon substrate, and a P-type well layer 94 is formed in the surface region of the N-type silicon substrate 96. In the P-type well layer 94, a P-type high-concentration well layer 103 is formed only under each of the P-type high-concentration body contact surfaces 93 in FIG. 12, along with an N-type source layer 102. A gate oxide film 95 is formed on the N-type silicon substrate 96 other than the portion corresponding to the P-type high-concentration well layer 103 and part of the N-type source layer 102. A gate electrode 91 is formed on the gate oxide films 95.

When this vertical MOS field-effect transistor is produced as shown in FIGS. 13 and 14, first, an oxide film and a polysilicon layer are formed successively on the N-type silicon substrate 96, and then patterning is performed to form the gate oxide film 95 and the gate electrode 91. Next, using the gate electrode 91 as a mask, P-type impurities are ion-implanted into the N-type silicon substrate 96, thereby forming the P-type well layer 94. Next, using the photoresist formed by patterning as a mask, N-type impurities are ion-implanted into the P-type well layer 94, thereby forming the N-type source layer 102. Next, using the photoresist formed by patterning as a mask, high-concentration P-type impurities are ion-implanted into the P-type well layer 94 only under each of the P-type high-concentration body contact surfaces 93 in FIG. 12, thereby forming the P-type high-concentration well layer 103 so as to be deeper than the depth of the P-type well layer 94 from the surface of the N-type silicon substrate 96 (FIG. 13). The P-type high-concentration well layer 103 serves to stabilize the threshold voltage of the vertical MOS field-effect transistor, to fix the base potential, and to improve the contact property.

Subsequently, as shown in FIGS. 15 and 16, a protective film 97 is formed on the gate electrode 91 and the N-type silicon substrate 96. Then, a contact hole 99 is formed on the P-type high-concentration well layer 103 and part of the N-type source layer 102 in the cross section of FIG. 15 taken along the line C-C′ in FIG. 12. Similarly, a contact hole 99 is formed on part of the N-type source layer 102 in the cross section of FIG. 16 taken along the line D-D′ in FIG. 12. Finally, a source electrode 98 is formed on the protective film 97. A drain electrode (not shown) is formed on the underside of the N-type silicon substrate 96.

In the cross section of FIG. 13 taken along the line C-C′ in FIG. 12, when the gate and source of the vertical MOS field-effect transistor are short-circuited, the withstand voltage between the drain and the source decreases with increasing the depths of the P-type well layer 94 and the P-type high-concentration well layer 103 from the surface of the N-type silicon substrate 96, if the impurity concentration and thickness of the N-type silicon substrate 96 are the same. In FIG. 13, the depth from the surface of the N-type silicon substrate 96 is deeper in the P-type high-concentration well layer 103 than in the P-type well layer 94. Therefore, compared to the case as shown in FIG. 10, where the depth from the surface of the N-type silicon substrate 66 is shallower in the P-type high-concentration well layer 73 than in the P-type well layer 64, the withstand voltage between the drain and the source decreases when the gate and source of the vertical MOS field-effect transistor are short-circuited. Thus, to provide the same withstand voltage as the structure in FIG. 10, it is necessary to reduce the impurity concentration or to increase the thickness of the N-type silicon substrate 96. This results in a large on-resistance.

In the cross section of FIG. 16 taken along the line D-D′ in FIG. 12, unlike the structure in FIG. 11, the source electrode 98 comes into contact with only the N-type source layer 102 via the contact hole 99. Therefore, even if a distance between the adjacent gate electrodes 91 is finer, the source electrode 98 can be brought into good contact with both the P-type well layer 94 and the P-type high-concentration well layer 103 via the contact hole 99 (i.e., a favorable contact property can be achieved with both the source contact surface 92 and the P-type high-concentration body contact surfaces 93).

However, in the cross section of FIG. 13 taken along the line C-C′ in FIG. 12, since the depth from the surface of the N-type silicon substrate 96 is deeper in the P-type high-concentration well layer 103 than in the P-type well layer 94, if the P-type high-concentration well layer 103 is formed by thermal diffusion, it is inevitable that the diffusion length of the P-type high-concentration well layer 103 also is increased in the direction perpendicular to the depth direction from the surface of the N-type silicon substrate 96. Accordingly, the diameter of the contact hole 99 has to be larger in FIG. 15, and thus it is difficult to make the distance between the adjacent gate electrodes 91 finer.

Moreover, in the cross section of FIG. 14 taken along the line D-D′ in FIG. 12, unlike the structure in FIG. 10, the P-type well layer 94 alone is present. Therefore, compared to the structure in which the P-type high-concentration well layer 73 is present in the P-type well layer 64 as shown in FIG. 10, the resistance component of the P-type well layer 94 is increased. Consequently, a parasitic bipolar transistor of the vertical MOS field-effect transistor is turned on easily, and the avalanche resistance becomes poor.

As described above, the conventional configuration has the following problems. The avalanche resistance is low due to the resistance component of the P-type well layer. The on-resistance is large due to the influence of the depth of the P-type high-concentration well layer deeper than that of the P-type well layer when measured from the surface of the silicon substrate. Moreover, it is difficult to make the distance between the adjacent gate electrodes finer due to the influence of the shape of a portion where the source electrode comes into contact with the source contact surface and the P-type high-concentration body contact surface and the influence of the depth of the P-type high-concentration well layer deeper than that of the P-type well layer when measured from the surface of the silicon substrate.

### SUMMARY OF THE INVENTION

To solve the above problems of the conventional art, it is an object of the present invention to provide a semiconductor device that can improve the avalanche resistance, make the distance between the adjacent gate electrodes finer easily, and reduce the on-resistance.

To achieve the object, a semiconductor device of the present invention includes the following: a first conductivity type semiconductor layer; a second conductivity type well layer that is formed in a surface region of the semiconductor layer, the second conductivity type being opposite to the first conductivity type; a first conductivity type source layer that is formed in a surface region of the well layer; a second conductivity type high-concentration well layer that is formed in the well layer so that its depth from the surface of the semiconductor layer is shallower than the well layer and deeper than the source layer and has a higher impurity concentration than the well layer; a gate electrode that is formed linearly across the semiconductor layer, the well layer, and the source layer via an insulating film; a first contact region that is connected electrically to the source layer; second contact regions that are arranged at predetermined intervals in the direction parallel to the gate electrode within the first contact region and connected electrically to the high-concentration well layer; and a source electrode that is connected electrically to the first contact region and the second contact regions. The source electrode is connected to either the first contact region or the second contact region in any cross section perpendicular to a longitudinal direction of the gate electrode.

In the context of the present invention, the “first conductivity type” means P-type or N-type conductivity.

In the configuration of the semiconductor device of the present invention, the high-concentration well layer is formed linearly in the well layer between the adjacent linear gate electrodes, so that the resistance component of the well layer can be reduced. Consequently, when the configuration of the semiconductor device of the present invention is applied, e.g., to a vertical MOS field-effect transistor, its parasitic bipolar transistor is not turned on easily, and thus the avalanche resistance can be improved.

At a cross section perpendicular to the longitudinal direction of the gate electrode in which the source electrode is in contact with the high-concentration well layer between the adjacent gate electrodes, the source electrode does not come into contact with the source layer, but only with the high-concentration well layer. Therefore, the resistance component of the contact surface between the source electrode and the high-concentration well layer can be reduced. Consequently, when the configuration of the semiconductor device of the present invention is applied, e.g., to a vertical MOS field-effect transistor, its parasitic bipolar transistor is not turned on easily, and thus the avalanche resistance can be improved.

Moreover, since the depth from the surface of the semiconductor layer is shallower in the high-concentration well layer than in the well layer, if the high-concentration well layer is formed by thermal diffusion, it is possible to reduce the diffusion length of the high-concentration well layer in the direction perpendicular to the depth direction from the surface of the semiconductor layer. Thus, the distance between the adjacent gate electrodes can be made finer. As described above, the depth from the surface of the semiconductor layer is shallower in the high-concentration well layer than in the well layer, and therefore when the gate and the source are short-circuited, the desired withstand voltage between the drain and the source can be obtained by either increasing the impurity concentration or reducing the thickness of the semiconductor layer. Consequently, the on-resistance can be reduced.

In the configuration of the semiconductor device of the present invention, it is preferable that the semiconductor layer is formed on a first conductivity type semiconductor substrate having a higher impurity concentration than the semiconductor layer, and a drain electrode is formed on a surface of the semiconductor substrate opposite to the surface in contact with the semiconductor layer.

In the configuration of the semiconductor device of the present invention, it is preferable that each of the second contact regions has a side that faces and is parallel to the gate electrode.

In the configuration of the semiconductor device of the present invention, it is preferable that each of the second contact regions has at least two sides that face the gate electrode, and an angle between the gate electrode and the side of the second contact region facing the gate electrode is larger than 0 and smaller than 90 degrees. In the configuration of the semiconductor device of the present invention, it is preferable that each of the second contact regions is rounded in shape.

With these preferred examples, the area of the first contact region can be increased further when a space between the second contact regions in the direction parallel to the gate electrode (i.e., a distance between the adjacent second contact regions) and a space between each of the second contact regions and the gate electrode in the direction perpendicular to the longitudinal direction of the gate electrode are the same. Consequently, when the configuration of the semiconductor device of the present invention is applied, e.g., to a vertical MOS filed-effect transistor, the resistance value of a current path in the vertical MOS field-effect transistor can be reduced, which in turn reduces the on-resistance of the vertical MOS field-effect transistor. In this case, if a width of the second contact region between the adjacent gate electrodes is the same, the on-resistance can be reduced while maintaining the contact property between the second contact region and the first contact region.

In the configuration of the semiconductor device of the present invention, it is preferable that the adjacent second contact regions are connected together by replacing a portion of the first contact region that is located between the adjacent second contact regions with the second contract region.

With this preferred example, the area of the second contact region can be increased, and the resistance component of the contact surface between the source electrode and the high-concentration well layer can be reduced. Consequently, when the configuration of the semiconductor device of the present invention is applied, e.g., to a vertical MOS field-effect transistor, its parasitic bipolar transistor is not turned on easily, and thus the avalanche resistance can be improved.

### BRIEF DESCRIPTION OF THE DRAWINGS

FIG. 1 a plan view showing the state after forming a source region in the surface of a vertical MOS field-effect transistor of Embodiment 1 of the present invention.

FIG. 2 is a cross-sectional view taken along the line A-A′ in FIG. 1 (also identified as a cross-sectional view taken along the line F-F′ in FIG. 6, a cross-sectional view taken along the line H-H′ in FIG. 7, or a cross-sectional view taken along the line J-J′ in FIG. 8).

FIG. 3 is a cross-sectional view taken along the line B-B′ in FIG. 1 (also identified as a cross-sectional view taken along the line G-G′ in FIG. 6 or a cross-sectional view taken along the line I-I′ in FIG. 7).

FIG. 4 is a cross-sectional view taken along the line A-A′ in FIG. 1 after forming a source electrode (also identified as a cross-sectional view taken along the line F-F′ in FIG. 6 after forming a source electrode, a cross-sectional view taken along the line H-H′ in FIG. 7 after forming a source electrode, or a cross-sectional view taken along the line J-J′ in FIG. 8 after forming a source electrode).

FIG. 5 is a cross-sectional view taken along the line B-B′ in FIG. 1 after forming a source electrode (also identified as a cross-sectional view taken along the line G-G′ in FIG. 6 after forming a source electrode or a cross-sectional view taken along the line I-I′ in FIG. 7 after forming a source electrode).

FIG. 6 is a plan view showing the state after forming a source region in the surface of a vertical MOS field-effect transistor of Embodiment 2 of the present invention.

FIG. 7 is a plan view showing the state after forming a source region in the surface of a vertical MOS field-effect transistor of Embodiment 3 of the present invention.

FIG. 8 is a plan view showing the state after forming a source region in the surface of a vertical MOS field-effect transistor of Embodiment 4 of the present invention.

FIG. 9 is a plan view showing the state after forming a source region in the surface of a conventional vertical MOS field-effect transistor.

FIG. 10 is a cross-sectional view taken along the line E-E′ in FIG. 9.

FIG. 11 is a cross-sectional view taken along the line E-E′ in FIG. 9 after forming a source electrode.

FIG. 12 is a plan view showing the state after forming a source region in the surface of another conventional vertical MOS filed-effect transistor.

FIG. 13 is a cross-sectional view taken along the line C-C′ in FIG. 12.

FIG. 14 is a cross-sectional view taken along the line D-D′ in FIG. 12.

FIG. 15 is a cross-sectional view taken along the line C-C′ in FIG. 12 after forming a source electrode.

FIG. 16 is a cross-sectional view taken along the line D-D′ in FIG. 12 after forming a source electrode.

### DESCRIPTION OF THE PREFERRED EmbodimentS

The present invention can provide a semiconductor device that can improve the avalanche resistance, make the distance between the adjacent gate electrodes finer easily, and reduce the on-resistance.

Hereinafter, the present invention will be described in detail by way of embodiments. In the following embodiments, a vertical MOS field-effect transistor is taken as an example of a semiconductor device. However, the present invention is not limited to the vertical MOS field-effect transistor, but also is applicable, e.g., to an insulated gate bipolar transistor (IGBT), etc.

### Embodiment 1

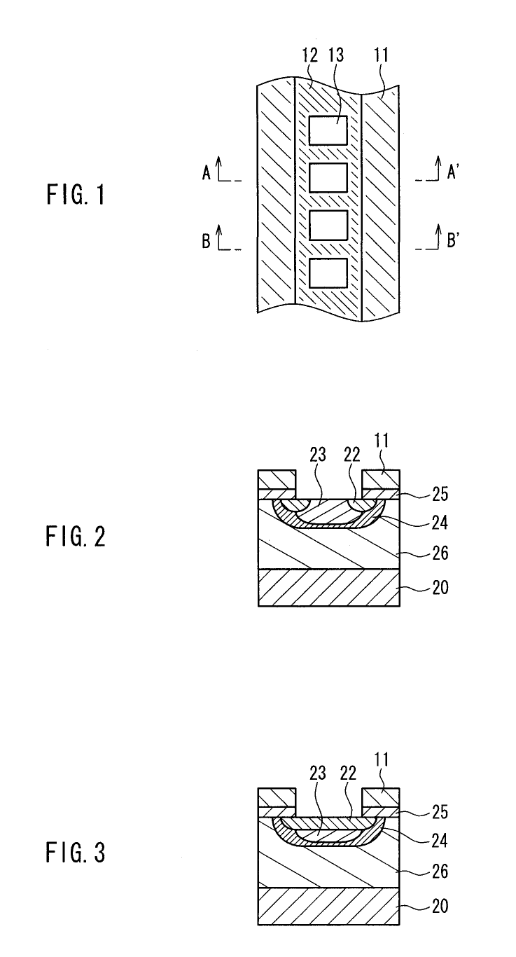

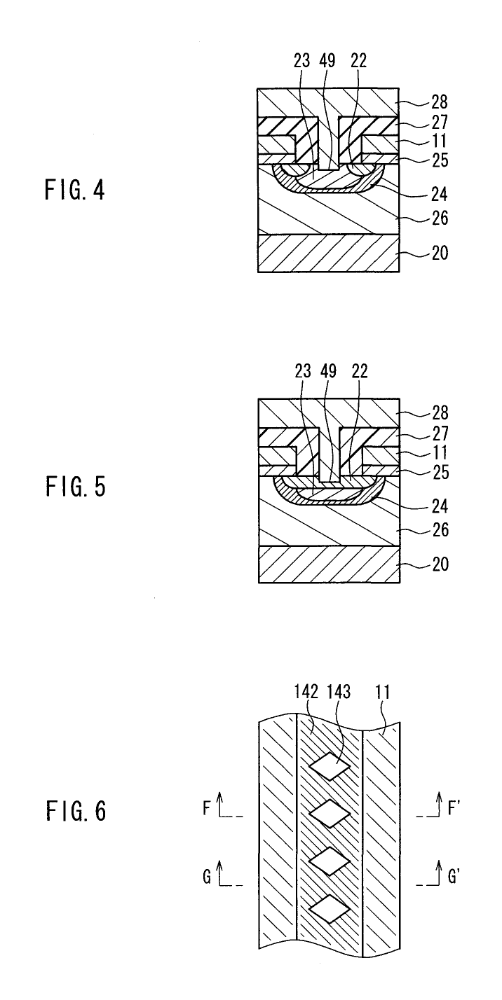

FIG. 1 is a plan view showing the state after forming a source region in the surface of a vertical MOS field-effect transistor of Embodiment 1 of the present invention. FIG. 2 is a cross-sectional view taken along the line A-A′ in FIG. 1. FIG. 3 is a cross-sectional view taken along the line B-B′ in FIG. 1. FIG. 4 is a cross-sectional view taken along the line A-A′ in FIG. 1 after forming a source electrode. FIG. 5 is a cross-sectional view taken along the line B-B′ in FIG. 1 after forming a source electrode.

In FIG. 1, reference numeral 11 is a gate electrode made of polysilicon, 12 is a source contact surface as a first contact region, and 13 are P-type high-concentration body contact surfaces as second contact regions.

In FIGS. 2 and 3, reference numeral 20 is an N-type silicon substrate, on which an N-type silicon layer 26 having a lower impurity concentration than the N-type silicon substrate 20 is formed. A P-type well layer 24 is formed in the surface region of the N-type silicon layer 26. An N-type source layer 22 is formed in the surface region of the P-type well layer 24 and connected electrically to the source contact surface 12 (FIG. 1). In the P-type well layer 24, a P-type high-concentration well layer 23 is formed so that its depth from the surface of the N-type silicon layer 26 is shallower than the P-type well layer 24 and deeper than the N-type source layer 22. The P-type high-concentration well layer 23 is connected electrically to the P-type high-concentration body contact surfaces 13 (FIG. 1). A linear gate oxide film 25 is formed on the N-type silicon layer 26 other than the portion corresponding to the P-type high-concentration well layer 23 and part of the N-type source layer 22. A linear gate electrode 11 is formed on the gate oxide film 25. In other words, a laminate of the gate oxide film 25 and the gate electrode 11 is formed across the N-type silicon layer 26, the P-type well layer 24, and the N-type source layer 22.

When this vertical MOS field-effect transistor is produced as shown in FIGS. 2 and 3, first, the N-type silicon layer 26 having a lower impurity concentration than the N-type silicon substrate 20 is formed on the N-type silicon substrate 20. Then, an oxide film and a polysilicon layer are formed successively on the N-type silicon layer 26, and patterning is performed to form the gate oxide film 25 and the gate electrode 11. Next, using the gate electrode 11 as a mask, boron (P-type impurity) is ion-implanted into the N-type silicon layer 26 to cause thermal diffusion, thereby forming the P-type well layer 24 in the surface region of the N-type silicon layer 26. Next, using the photoresist formed by patterning as a mask, high-concentration boron is ion-implanted into the N-type silicon layer 26 to cause thermal diffusion, thereby forming the P-type high-concentration well layer 23 so that its depth from the surface of the N-type silicon layer 26 is shallower than the P-type well layer 24. Next, using the photoresist formed by patterning as a mask, arsenic (N-type impurity) is implanted into the N-type silicon layer 26, thereby forming the N-type source layer 22 in the surface region of the P-type well layer 24 so that the P-type high-concentration body contact surfaces 13, each of which has the same area and the same rectangular shape with one side facing and being parallel to the gate electrode 11, are arranged at predetermined intervals in the direction parallel to the gate electrode 11 within the source contact surface 12, as shown in FIG. 1. In FIG. 1, although each of the P-type high-concentration body contact surfaces 13 is in the form of a rectangle, it may have another shape as long as one side faces and is parallel to gate electrode 11, such as a square.

Subsequently, as shown in FIGS. 4 and 5, a protective film 27 made of phospho-silicate glass (PSG) is formed on the gate electrode 11 and the N-type silicon layer 26. Then, a contact hole 49 is formed by etching. Finally, an aluminum layer is formed on the protective film 27 and the N-type silicon layer 26, and patterning is performed to form a source electrode 28. A drain electrode (not shown) is formed on the underside of the N-type silicon substrate 20.

As shown in FIG. 4, the source electrode 28 is connected electrically to only the P-type high-concentration well layer 23 (the P-type high-concentration body contact surface 13) via the contact hole 49 in the cross section taken along the line A-A′ in FIG. 1.

As shown in FIG. 5, the source electrode 28 is connected electrically to only the N-type source layer 22 (the source contact surface 12) via the contact hole 49 in the cross section taken along the line B-B′ in FIG. 1.

In the configuration of this embodiment, the P-type high-concentration well layer 23 is formed linearly in the P-type well layer 24 between the adjacent linear gate electrodes 11, so that the resistance component of the P-type well layer 24 can be reduced. Consequently, a parasitic bipolar transistor of the vertical MOS field-effect transistor is not turned on easily, thus improving the avalanche resistance.

At a cross section (FIG. 4) perpendicular to the longitudinal direction of the gate electrode 11 in which the source electrode 28 is in contact with the P-type high-concentration well layer 23 between the adjacent gate electrodes 11, the source electrode 28 does not come into contact with the N-type source layer 22, but only with the P-type high-concentration well layer 23. Therefore, the resistance component of the contact surface between the source electrode 28 and the P-type high-concentration well layer 23 can be reduced. Consequently, a parasitic bipolar transistor of the vertical MOS field-effect transistor is not turned on easily, thus improving the avalanche resistance.

Moreover, since the depth from the surface of the N-type silicon layer 26 is shallower in the P-type high-concentration well layer 23 than in the P-type well layer 24, if the P-type high-concentration well layer 23 is formed by thermal diffusion, it is possible to reduce the diffusion length of the P-type high-concentration well layer 23 in the direction perpendicular to the depth direction from the surface of the N-type silicon layer 26. Thus, the distance between the adjacent gate electrodes 11 can be made finer. As described above, the depth from the surface of the N-type silicon layer 26 is shallower in the P-type high-concentration well layer 23 than in the P-type well layer 24, and therefore when the gate and source of the vertical MOS field-effect transistor are short-circuited, the desired withstand voltage between the drain and the source can be obtained by either increasing the impurity concentration of the N-type silicon layer 26 or reducing the thickness of the N-type silicon layer 26. Consequently, the on-resistance of the vertical MOS field-effect transistor can be reduced.

### Embodiment 2

FIG. 6 is a plan view showing the state after forming a source region in the surface of a vertical MOS field-effect transistor of Embodiment 2 of the present invention. Since cross-sectional views taken along the line F-F′ and the line G-G′ in FIG. 6 are the same as FIGS. 2 to 5 in Embodiment 1, this embodiment also refers to FIGS. 2 to 5. That is, FIG. 2 is identified as the cross-sectional view taken along the line F-F′ in FIG. 6, FIG. 3 is identified as the cross-sectional view taken along the line G-G′ in FIG. 6, FIG. 4 is identified as the cross-sectional view taken along the F-F′ in FIG. 6 after forming a source electrode, and FIG. 5 is identified as the cross-sectional view taken along the G-G′ in FIG. 6 after forming a source electrode.

In FIG. 6, reference numeral 11 is a gate electrode made of polysilicon, 142 is a source contact surface as a first contact region, and 143 are P-type high-concentration body contact surfaces as second contact regions.

In FIGS. 2 and 3, reference numeral 20 is an N-type silicon substrate, on which an N-type silicon layer 26 having a lower impurity concentration than the N-type silicon substrate 20 is formed. A P-type well layer 24 is formed in the surface region of the N-type silicon layer 26. An N-type source layer 22 is formed in the surface region of the P-type well layer 24 and connected electrically to the source contact surface 12 (FIG. 1). In the P-type well layer 24, a P-type high-concentration well layer 23 is formed so that its depth from the surface of the N-type silicon layer 26 is shallower than the P-type well layer 24 and deeper than the N-type source layer 22. The P-type high-concentration well layer 23 is connected electrically to the P-type high-concentration body contact surfaces 13 (FIG. 1). A linear gate oxide film 25 is formed on the N-type silicon layer 26 other than the portion corresponding to the P-type high-concentration well layer 23 and part of the N-type source layer 22. A linear gate electrode 11 is formed on the gate oxide film 25. In other words, a laminate of the gate oxide film 25 and the gate electrode 11 is formed across the N-type silicon layer 26, the P-type well layer 24, and the N-type source layer 22.

When this vertical MOS field-effect transistor is produced as shown in FIGS. 2 and 3, first, the N-type silicon layer 26 having a lower impurity concentration than the N-type silicon substrate 20 is formed on the N-type silicon substrate 20. Then, an oxide film and a polysilicon layer are formed successively on the N-type silicon layer 26, and patterning is performed to form the gate oxide film 25 and the gate electrode 11. Next, using the gate electrode 11 as a mask, boron (P-type impurity) is ion-implanted into the N-type silicon layer 26 to cause thermal diffusion, thereby forming the P-type well layer 24 in the surface region of the N-type silicon layer 26. Next, using the photoresist formed by patterning as a mask, high-concentration boron is ion-implanted into the N-type silicon layer 26 to cause thermal diffusion, thereby forming the P-type high-concentration well layer 23 so that its depth from the surface of the N-type silicon layer 26 is shallower than the P-type well layer 24. Next, using the photoresist formed by patterning as a mask, arsenic (N-type impurity) is implanted into the N-type silicon layer 26, thereby forming the N-type source layer 22 in the surface region of the P-type well layer 24 so that the P-type high-concentration body contact surfaces 143, each of which has the same area and the same shape with at least two sides facing the gate electrode 11, are arranged at predetermined intervals in the direction parallel to the gate electrode 11 within the source contact surface 142, as shown in FIG. 6. The angle between the gate electrode 11 and the side of the P-type high-concentration body contact surface 143 facing the gate electrode 11 is larger than 0 and smaller than 90 degrees. In FIG. 6, although each of the P-type high-concentration body contact surfaces 143 is in the form of a rhombus, it may have another shape as long as at least two sides face the gate electrode 11, and the angle between the side and the gate electrode 11 is larger than 0 and smaller than 90 degrees.

Subsequently, as shown in FIGS. 4 and 5, a protective film 27 made of PSG is formed on the gate electrode 11 and the N-type silicon layer 26. Then, a contact hole 49 is formed by etching. Finally, an aluminum layer is formed on the protective film 27 and the N-type silicon layer 26, and patterning is performed to form a source electrode 28. A drain electrode (not shown) is formed on the underside of the N-type silicon substrate 20.

As shown in FIG. 4, the source electrode 28 is connected electrically to only the P-type high-concentration well layer 23 (the P-type high-concentration body contact surface 143) via the contact hole 49 in the cross section taken along the line F-F′ in FIG. 6.

As shown in FIG. 5, the source electrode 28 is connected electrically to only the N-type source layer 22 (the source contact surface 142) via the contact hole 49 in the cross section taken along the line G-G′ in FIG. 6.

In the configuration of this embodiment, as shown in FIG. 6, each of the P-type high-concentration body contact surfaces 143 has a shape so that at least two sides face the gate electrode 11, and the angle between the gate electrode 11 and the side of the P-type high-concentration body contact surface 143 facing the gate electrode 11 is larger than 0 and smaller than 90 degrees, instead of the rectangular shape with one side facing and being parallel to the gate electrode 11 in Embodiment 1 (FIG. 1). Accordingly, the area of the source contact surface 142 in FIG. 6 of this embodiment can be larger than that of the source contact surface 12 in FIG. 1 of Embodiment 1 when a space between the P-type high-concentration body contact surfaces 13 in the direction parallel to the gate electrode 11 (i.e., a distance between the adjacent P-type high-concentration body contact surfaces 13) and a space between the gate electrodes 11 in the direction perpendicular to the longitudinal direction of the gate electrode 11 in FIG. 1 of Embodiment 1 are respectively the same as a space between the P-type high-concentration body contact surfaces 143 in the direction parallel to the gate electrode 11 (i.e., a distance between the adjacent P-type high-concentration body contact surfaces 143) and a space between the gate electrodes 11 in the direction perpendicular to the longitudinal direction of the gate electrode 11 in FIG. 6 of this embodiment. Consequently, the resistance value of a current path in the vertical MOS field-effect transistor can be reduced, which in turn reduces the on-resistance of the vertical MOS field-effect transistor. In this case, if a width of the P-type high-concentration body contact surface 13 between the adjacent gate electrodes 11 in FIG. 1 of Embodiment 1 is the same as that of the P-type high-concentration body contact surface 143 between the adjacent gate electrodes 11 in FIG. 6 of this embodiment, the on-resistance can be reduced while maintaining the contact property between the P-type high-concentration body contact surface 143 and the source contact surface 142.

### Embodiment 3

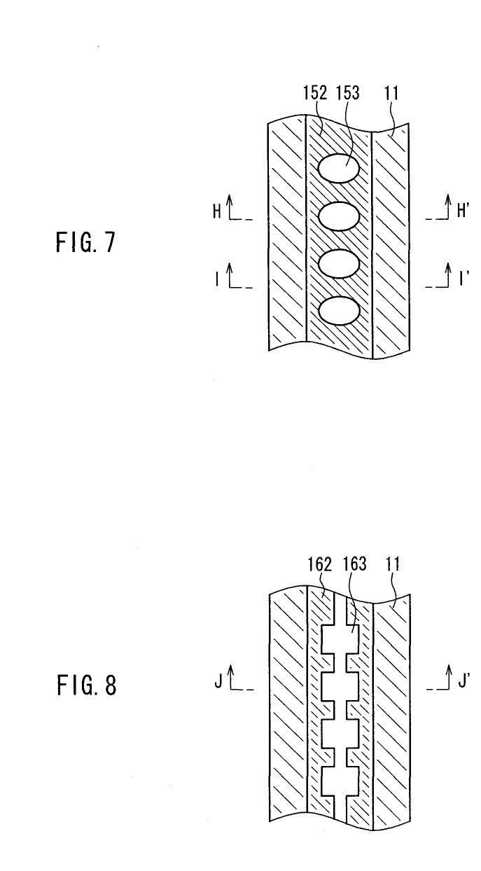

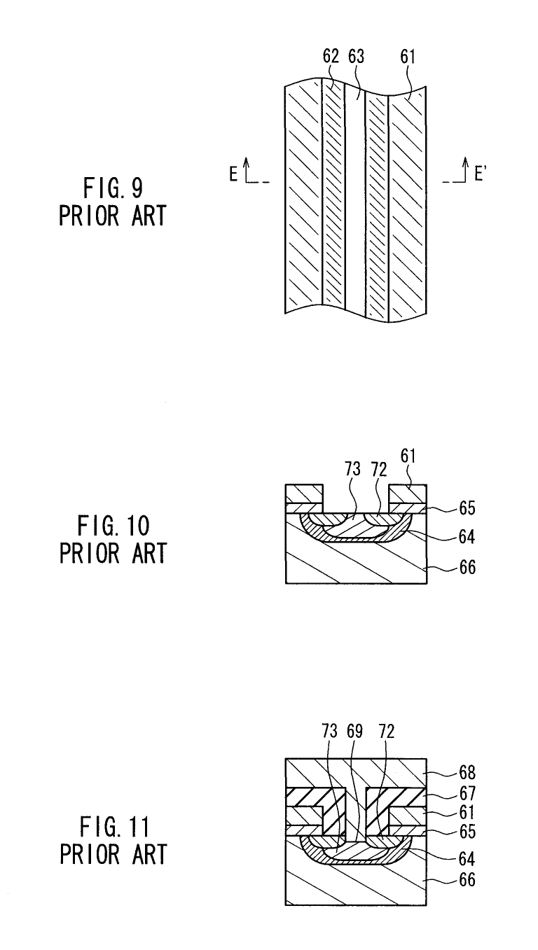

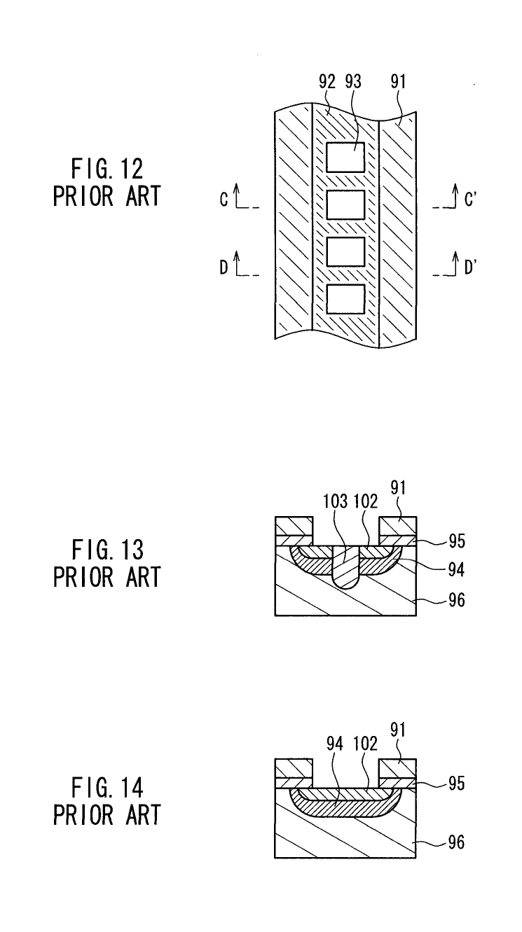

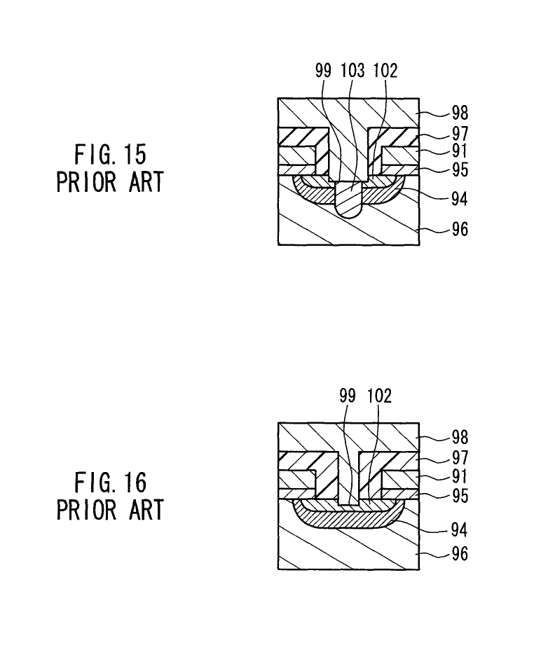

FIG. 7 is a plan view showing the state after forming a source region in the surface of a vertical MOS field-effect transistor of Embodiment 3 of the present invention. Since cross-sectional views taken along the line H-H′ and the line I-I′ in FIG. 7 are the same as FIGS. 2 to 5 in Embodiment 1, this embodiment also refers to FIGS. 2 to 5. That is, FIG. 2 is identified as the cross-sectional view taken along the line H-H′ in FIG. 7, FIG. 3 is identified as the cross-sectional view taken along the line I-I′ in FIG. 7, FIG. 4 is identified as the cross-sectional view taken along the H-H′ in FIG. 7 after forming a source electrode, and FIG. 5 is identified as the cross-sectional view taken along the I-I′ in FIG. 7 after forming a source electrode.

In FIG. 7, reference numeral 11 is a gate electrode made of polysilicon, 152 is a source contact surface as a first contact region, and 153 are P-type high-concentration body contact surfaces as second contact regions.

In FIGS. 2 and 3, reference numeral 20 is an N-type silicon substrate, on which an N-type silicon layer 26 having a lower impurity concentration than the N-type silicon substrate 20 is formed. A P-type well layer 24 is formed in the surface region of the N-type silicon layer 26. An N-type source layer 22 is formed in the surface region of the P-type well layer 24 and connected electrically to the source contact surface 12 (FIG. 1). In the P-type well layer 24, a P-type high-concentration well layer 23 is formed so that its depth from the surface of the N-type silicon layer 26 is shallower than the P-type well layer 24 and deeper than the N-type source layer 22. The P-type high-concentration well layer 23 is connected electrically to the P-type high-concentration body contact surfaces 13 (FIG. 1). A linear gate oxide film 25 is formed on the N-type silicon layer 26 other than the portion corresponding to the P-type high-concentration well layer 23 and part of the N-type source layer 22. A linear gate electrode 11 is formed on the gate oxide film 25. In other words, a laminate of the gate oxide film 25 and the gate electrode 11 is formed across the N-type silicon layer 26, the P-type well layer 24, and the N-type source layer 22.

When this vertical MOS field-effect transistor is produced as shown in FIGS. 2 and 3, first, the N-type silicon layer 26 having a lower impurity concentration than the N-type silicon substrate 20 is formed on the N-type silicon substrate 20. Then, an oxide film and a polysilicon layer are formed successively on the N-type silicon layer 26, and patterning is performed to form the gate oxide film 25 and the gate electrode 11. Next, using the gate electrode 11 as a mask, boron (P-type impurity) is ion-implanted into the N-type silicon layer 26 to cause thermal diffusion, thereby forming the P-type well layer 24 in the surface region of the N-type silicon layer 26. Next, using the photoresist formed by patterning as a mask, high-concentration boron is ion-implanted into the N-type silicon layer 26 to cause thermal diffusion, thereby forming the P-type high-concentration well layer 23 so that its depth from the surface of the N-type silicon layer 26 is shallower than the P-type well layer 24. Next, using the photoresist formed by patterning as a mask, arsenic (N-type impurity) is implanted into the N-type silicon layer 26, thereby forming the N-type source layer 22 in the surface region of the P-type well layer 24 so that the P-type high-concentration body contact surfaces 153, each of which has the same area and the same rounded shape, are arranged at predetermined intervals in the direction parallel to the gate electrode 11 within the source contact surface 152, as shown in FIG. 7. In FIG. 7, although each of the P-type high-concentration body contact surfaces 153 is in the form of an ellipse, it may be a perfect circle.

Subsequently, as shown in FIGS. 4 and 5, a protective film 27 made of PSG is formed on the gate electrode 11 and the N-type silicon layer 26. Then, a contact hole 49 is formed by etching. Finally, an aluminum layer is formed on the protective film 27 and the N-type silicon layer 26, and patterning is performed to form a source electrode 28. A drain electrode (not shown) is formed on the underside of the N-type silicon substrate 20.

As shown in FIG. 4, the source electrode 28 is connected electrically to only the P-type high-concentration well layer 23 (the P-type high-concentration body contact surface 153) via the contact hole 49 in the cross section taken along the line H-H′ in FIG. 7.

As shown in FIG. 5, the source electrode 28 is connected electrically to only the N-type source layer 22 (the source contact surface 152) via the contact hole 49 in the cross section taken along the line I-I′ in FIG. 7.

In the configuration of this embodiment, as shown in FIG. 7, each of the P-type high-concentration body contact surfaces 153 has a rounded shape, instead of the rectangular shape with one side facing and being parallel to the gate electrode 11 in Embodiment 1 (FIG. 1). Accordingly, the area of the source contact surface 152 in FIG. 7 of this embodiment can be larger than that of the source contact surface 12 in FIG. 1 of Embodiment 1 when a space between the P-type high-concentration body contact surfaces 13 in the direction parallel to the gate electrode 11 (i.e., a distance between the adjacent P-type high-concentration body contact surfaces 13) and a space between each of the P-type high-concentration body contact surfaces 13 and the gate electrode 11 in the direction perpendicular to the longitudinal direction of the gate electrode 11 in FIG. 1 of Embodiment 1 are respectively the same as a space between the P-type high-concentration body contact surfaces 153 in the direction parallel to the gate electrode 11 (i.e., a distance between the adjacent P-type high-concentration body contact surfaces 153) and a space between each of the P-type high-concentration body contact surfaces 153 and the gate electrode 11 in the direction perpendicular to the longitudinal direction of the gate electrode 11 in FIG. 7 of this embodiment. Consequently, the resistance value of a current path in the vertical MOS field-effect transistor can be reduced, which in turn reduces the on-resistance of the vertical MOS filed-effect transistor. In this case, if a width of the P-type high-concentration body contact surface 13 between the adjacent gate electrodes 11 in FIG. 1 of Embodiment 1 is the same as that of the P-type high-concentration body contact surface 153 between the adjacent gate electrodes 11 in FIG. 7 of this embodiment, the on-resistance can be reduced while maintaining the contact property between the P-type high-concentration body contact surface 153 and the source contact surface 152.

### Embodiment 4

FIG. 8 is a plan view showing the state after forming a source region in the surface of a vertical MOS field-effect transistor of Embodiment 4 of the present invention. Since a cross-sectional view taken along the line J-J′ in FIG. 8 is the same as FIGS. 2 and 4 in Embodiment 1, this embodiment also refers to FIGS. 2 and 4. That is, FIG. 2 is identified as the cross-sectional view taken along the line J-J′ in FIG. 8, and FIG. 4 is identified as the cross-sectional view taken along the J-J′ in FIG. 8 after forming a source electrode.

In FIG. 8, reference numeral 11 is a gate electrode made of polysilicon, 162 is a source contact surface, and 163 is a P-type high-concentration body contact surface.

In FIG. 2, reference numeral 20 is an N-type silicon substrate, on which an N-type silicon layer 26 having a lower impurity concentration than the N-type silicon substrate 20 is formed. A P-type well layer 24 is formed in the surface region of the N-type silicon layer 26. An N-type source layer 22 is formed in the surface region of the P-type well layer 24 and connected electrically to the source contact surface 12 (FIG. 1). In the P-type well layer 24, a P-type high-concentration well layer 23 is formed so that its depth from the surface of the N-type silicon layer 26 is shallower than the P-type well layer 24 and deeper than the N-type source layer 22. The P-type high-concentration well layer 23 is connected electrically to the P-type high-concentration body contact surfaces 13 (FIG. 1). A linear gate oxide film 25 is formed on the N-type silicon layer 26 other than the portion corresponding to the P-type high-concentration well layer 23 and part of the N-type source layer 22. A linear gate electrode 11 is formed on the gate oxide film 25. In other words, a laminate of the gate oxide film 25 and the gate electrode 11 is formed across the N-type silicon layer 26, the P-type well layer 24, and the N-type source layer 22.

When this vertical MOS field-effect transistor is produced as shown in FIGS. 2 and 3, first, the N-type silicon layer 26 having a lower impurity concentration than the N-type silicon substrate 20 is formed on the N-type silicon substrate 20. Then, an oxide film and a polysilicon layer are formed successively on the N-type silicon layer 26, and patterning is performed to form the gate oxide film 25 and the gate electrode 11. Next, using the gate electrode 11 as a mask, boron (P-type impurity) is ion-implanted into the N-type silicon layer 26 to cause thermal diffusion, thereby forming the P-type well layer 24 in the surface region of the N-type silicon layer 26. Next, using the photoresist formed by patterning as a mask, high-concentration boron is ion-implanted into the N-type silicon layer 26 to cause thermal diffusion, thereby forming the P-type high-concentration well layer 23 so that its depth from the surface of the N-type silicon layer 26 is shallower than the P-type well layer 24. Next, using the photoresist formed by patterning as a mask, arsenic (N-type impurity) is implanted into the N-type silicon layer 26, thereby forming the N-type source layer 22 so that the adjacent P-type high-concentration body contact surfaces 163 are connected together by replacing a portion of the source contact surface 162 that is located between the adjacent P-type high-concentration body contact surfaces 163 with a region of the P-type high-concentration body contact surface 163, as shown in FIG. 8.

Subsequently, as shown in FIG. 4, a protective film 27 made of PSG is formed on the gate electrode 11 and the N-type silicon layer 26. Then, a contact hole 49 is formed by etching. Finally, an aluminum layer is formed on the protective film 27 and the N-type silicon layer 26, and patterning is performed to form a source electrode 28. A drain electrode (not shown) is formed on the underside of the N-type silicon substrate 20.

In the configuration of this embodiment, as shown in FIG. 8, the adjacent P-type high-concentration body contact surfaces 163 are connected together by replacing a portion of the source contact surface 162 that is located between the adjacent P-type high-concentration body contact surfaces 163 with a region of the P-type high-concentration body contact surface 163. Thus, the area of the P-type high-concentration body contact surface 163 can be increased. Consequently, the resistance component of the contact surface between the source electrode 28 and the P-type high-concentration well layer 23 is reduced, and a parasitic bipolar transistor of the vertical MOS field-effect transistor is not turned on easily, thus improving the avalanche resistance.

In this embodiment, a portion of the source contact surface 12 that is located between the rectangular P-type high-concentration body contact surfaces 13 in FIG. 1 of Embodiment 1 is replaced by a region of the P-type high-concentration body contact surface 13. However, the same effect also can be obtained, e.g., by replacing a portion of the source contact surface 142 that is located between the rhombic P-type high-concentration body contact surfaces 143 in FIG. 6 of Embodiment 2 with a region of the P-type high-concentration body contact surface 143, or by replacing a portion of the source contact surface 152 that is located between the elliptic P-type high-concentration body contact surfaces 153 in FIG. 7 of Embodiment 3 with a region of the P-type high-concentration body contact surface 153.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device comprising:
a first conductivity type semiconductor layer;
a second conductivity type well layer that is formed in a surface region of the semiconductor layer, the second conductivity type being opposite to the first conductivity type;
a first conductivity type source layer that is formed in a surface region of the well layer;
a second conductivity type high-concentration well layer that is formed in the well layer so that its depth from the surface of the semiconductor layer is shallower than the well layer and deeper than the source layer and has a higher impurity concentration than the well layer;
a gate electrode that is formed linearly across the semiconductor layer, the well layer, and the source layer via an insulating film;
a first contact region that is connected electrically to the source layer;
second contact regions that are arranged at predetermined intervals in a direction parallel to the gate electrode within the first contact region and connected electrically to the high-concentration well layer; and
a source electrode that is connected electrically to the first contact region and the second contact regions,
wherein the source electrode is connected to either the first contact region or the second contact region in any cross section perpendicular to a longitudinal direction of the gate electrode.

2. The semiconductor device according to claim 1, wherein the semiconductor layer is formed on a first conductivity type semiconductor substrate having a higher impurity concentration than the semiconductor layer, and a drain electrode is formed on a surface of the semiconductor substrate opposite to the surface in contact with the semiconductor layer.

3. The semiconductor device according to claim 1, wherein each of the second contact regions has a side that faces and is parallel to the gate electrode.

4. The semiconductor device according to claim 1, wherein each of the second contact regions has at least two sides that face the gate electrode, and an angle between the gate electrode and the side of the second contact region facing the gate electrode is larger than 0 and smaller than 90 degrees.

5. The semiconductor device according to claim 1, wherein each of the second contact regions is rounded in shape.

6. The semiconductor device according to claim 1, wherein the adjacent second contact regions are connected together by replacing a portion of the first contact region that is located between the adjacent second contact regions with the second contact region.
